(19) United States
(12) Patent Application Publication
(10) Pub. No.: US 2024/0297241 A1
(43) Pub. Date: Sep. 5, 2024

(54) QUBIT ELEMENT

(71) Applicant: Rheinisch-Westfälische Technische Hochschule (RWTH Aachen), Aachen (DE)

(72) Inventors: Lars Schreiber, Aachen (DE); Matthias Künne, Jülich (DE)

(21) Appl. No.: 18/569,751

(22) PCT Filed: Jun. 14, 2021
(86) PCT No.: PCT/EP2021/065943

§ 371 Date: Dec. 13, 2023

(51) Int. Cl. H01L 29/66; G06N 10/40; H01L 29/12

(52) U.S. Cl. CPC H01L 29/66977; G06N 10/40; H01L 29/122

(57) ABSTRACT

Qubit element (1), comprising
quantum well structure (2), within which a quantum well (3) is formed along a first direction (x),
an electrode arrangement (4) adapted to restrict a movement of a charge carrier in the quantum well (3) in and against a second direction (y) and in and against a third direction (z), in order to form a quantum dot (5), wherein the first direction (x), the second direction (y), and the third direction (z) are respectively perpendicular to one another in pairs,
a base layer (6) formed from strained silicon adjacent to the quantum well structure (2) against the first direction (x).

### CROSS REFERENCE TO RELATED APPLICATIONS

This application is a national phase entry based on International patent application number PCT/EP2021/065943 filed on 14 Jun. 2021 and published as WO 2022/262934 A1. The above-referenced international application is hereby incorporated by reference in its entirety.

### BACKGROUND OF THE INVENTION

### Field of the Invention

The invention relates to a qubit element as well as to a use of the qubit element and a manufacturing method for the qubit element.

### Brief Description of the Related Art

Conventional computers are based on representing information in binary code. Bits which can be implemented by different physical concepts are used for storing and processing data. All these physical concepts belong to classical physics. In contrast, quantum computers are based on quantum physical principles. Quantum computers use so-called quantum bits (qubits for short) instead of bits. Qubits are quantum mechanical two-state systems. A qubit has two eigenstates in which it can be situated. A qubit can moreover also be situated in any desired superposition of its two eigenstates on account of quantum physical effects. It is thereby possible to execute algorithms with a quantum computer which cannot be executed with a conventional computer. This can considerably shorten the computing time of specific operations.

The spin of a charge carrier can be used as a qubit. It is, however, necessary for this purpose to have access to the charge carrier in such a way that its spin can be determined and influenced. It is known for this purpose to locate charge carriers in quantum dots. Semiconductors known for this purpose, however, do not allow satisfactory control over the spin.

### SUMMARY OF THE INVENTION

Starting from the described state of the art, the object of the present invention is to present a qubit element with which the spin of a charge carrier can be controlled particularly well. A corresponding use and a manufacturing method are also to be presented.

These objects are achieved with a qubit element, a use, and a manufacturing method according to the independent claims. Further advantageous embodiments are specified in the dependent claims. The features presented in the claims and in the description can be combined with one another in any desired technologically expedient manner.

According to the invention, a qubit element is presented which comprises:
quantum well structure, within which a quantum well is formed along a first direction,
an electrode arrangement adapted to restrict a movement of a charge carrier in the quantum well in and against a second direction and in and against a third direction, in order to form a quantum dot, wherein the first direction, the second direction, and the third direction are respectively perpendicular to one another in pairs,
a base layer formed from strained silicon adjacent to the quantum well structure against the first direction.

The term qubit is used herein—as is generally usual—for the abstract concept of a quantum mechanical two-state system which can be used for quantum computing. A qubit element is to be understood here—in distinction from the abstract concept—as a device with which a qubit can be implemented. The term “device for implementing a qubit” can therefore also be used instead of the term “qubit element”. The qubit element is, in particular, a semiconductor structure. The term “semiconductor structure for implementing a qubit” can also be used in this case instead of the term “qubit element”. The qubit can, in particular, be part of a device having a plurality of qubit elements formed as described. Such a device is likewise part of the invention.

A quantum dot can be formed in the qubit element. The movement of a charge carrier in the quantum dot is restricted in all directions to such an extent that the charge carrier can only adopt discrete energy states. A quantum dot can be referred to as zero-dimensional. A charge carrier can be an electron or a hole. A charge carrier in a quantum dot can be used for implementing a qubit. The spin of a charge carrier in a quantum dot can, in particular, be used for implementing a qubit.

The qubit element is described using a coordinate system having a first direction, a second direction, and a third direction, wherein the three directions are respectively perpendicular to one another in pairs.

The qubit element has a quantum well structure. A quantum well is formed in the quantum well structure. A quantum well is a potential curve that restricts in one direction the movement of a charge carrier located therein. The quantum well of the quantum well structure is formed along the first direction. This means that the movement of a charge carrier in the quantum well in and against the first direction is restricted to the quantum well. The potential that forms the quantum well can be the valence band or the conduction band of a semiconductor layer structure.

The movement of a charge carrier in and against the first direction can be restricted by the quantum well structure. A restriction of the movement of the charge carrier in and against the other two directions is possible by electrical fields that can be generated by applying electrical voltages to electrodes (which can also be referred to as “gates”). For this purpose, the qubit element has an electrode array. The electrode array is formed such that the movement of the charge carrier in the quantum well in and against the second and third directions can be restricted.

The electrode array is preferably spaced apart from the quantum well structure in the first direction. The electrode array thus lies above the quantum well structure, if the first direction points from bottom to top. The electrode array is preferably electrically insulated from the quantum well structure and in this respect does not lie directly against the quantum well structure. The electrode array is preferably spaced apart from the quantum well structure by an oxide layer and/or a top layer. The oxide layer serves for electrical insulation, the top layer for adhesion of the electrode array to the oxide layer. The electrode array is preferably spaced apart from the edge of the quantum well structure at a distance of 10 to 200 nm [nanometers]. This relates to the edge of the quantum well structure which lies closest to the electrode array.

The quantum well structure could basically be grown directly onto a wafer, in particular a silicon wafer. Lattice defects can, however, occur independently of the lattice structure of the quantum well structure. This applies, in particular, when the quantum well structure does not have silicon with the naturally occurring lattice constant on its side facing the wafer. This relates to the underside of the quantum well structure, if the first direction points from bottom to top. The advantages of the described qubit element can be used particularly well in the case that the quantum well structure has a lattice constant on its surface pointing against the first direction which deviates from the lattice constant naturally present in the case of silicon.

The described qubit element can be manufactured particularly easily because of the base layer. This applies, in particular, with respect to a case in which the quantum well structure is grown directly onto a silicon wafer or onto a transition layer.

The base layer is adjacent to the quantum well structure against the first direction. The base layer thus is adjacent to the quantum well structure at the bottom, if the first direction points from bottom to top. The base layer is formed from strained silicon. It is to be understood here—as is generally usual—that the silicon has a different lattice constant than the naturally present lattice constant. The naturally present lattice constant of silicon is around 0.5 nm [nanometers]. Silicon whose lattice constant deviates from the naturally occurring value by at least 0.2%, in particular at least 1%, is to be considered here as strained silicon. The expression that “the base layer is formed from silicon which has a lattice constant which deviates from the lattice constant naturally occurring in silicon by at least 0.2%, in particular at least 1%” can therefore also be used instead of the term “strained silicon”.

It is preferred that the base layer is at most 20 nm [nanometers] thick. The thickness of the base layer is the extent of the base layer in the first direction. The thickness of the base layer is preferably between 1 and 10 nm [nanometers].

The base layer preferably has the lattice constant which the quantum well structure has at the interface between the base layer and the quantum well structure. The base layer therefore merges into the quantum well structure without changing the lattice constant. Particularly few lattice defects occur in the quantum well structure as a result. This allows particularly good control of the spin of a charge carrier in the quantum dot.

In a preferred embodiment, the qubit element further comprises an insulation layer of silicon dioxide abutting the base layer on a side of the base layer opposite the quantum well structure.

The silicon dioxide layer is referred to here as insulation layer because the silicon dioxide can be used for electrical insulation between the base layer and a further layer adjacent to the insulation layer. The insulation layer can be amorphous. The insulation layer preferably has a thickness in the range of 5 and 30 nm [nanometers]. The thickness of the insulation layer is the extent of the insulation layer in the first direction.

In a further preferred embodiment of the qubit element, the quantum well structure has three layers following one another in the first direction, of which the middle layer is formed from strained silicon, and of which the two remaining layers are respectively formed from silicon and germanium.

The strained silicon of the middle layer has a lattice constant which deviates from the natural lattice constant of silicon. In this respect, the silicon of the middle layers is strained. The material of the middle layer can be, in particular, silicon with a lattice constant which corresponds to the lattice constant of the material of the remaining layers. This expression can be used instead of the term “strained silicon” for the material of the middle layer.

The two remaining layers are preferably formed from silicon-germanium or germanium-silicon. As is usual, silicon-germanium refers to a semiconductor material of silicon and germanium which has more silicon than germanium. Germanium-silicon is correspondingly a semiconductor material which has more germanium than silicon. The material of the remaining layers of the quantum well structure (i.e., of the layers of the quantum well structure which are not the middle layer) preferably has a silicon content in the range of 60 and 80% or in the range of 20 and 40%. The material is preferably Si_{0.7}Ge_{0.3} or Ge_{0.7}Si_{0.3}.

The conduction band forms a quantum well due to the layer sequence silicon-germanium, silicon, silicon-germanium. The movement of electrons as charge carriers can thereby be restricted. The spin of an electron can then be used for implementing a qubit. The valence band and the conduction band form a quantum well due to the layer sequence germanium-silicon, silicon, germanium-silicon. The movement of holes and/or electrons as charge carriers can thereby be restricted. The spin of an electron or hole can then be used for implementing a qubit.

The middle layer preferably has a thickness in the range of 3 to 12 nm [nanometers]. The remaining layers of the quantum well structure preferably have a thickness in the range of 30 and 70 nm [nanometers]. The thickness of a layer is here respectively the extent of this layer in the first direction.

In a further preferred embodiment, the qubit element further comprises a magnet arranged spaced apart against the first direction from the quantum well structure.

A gradient of the magnetic field of the magnet results in a spin-orbit coupling of the states of the charge carrier in the quantum dot and the energy splitting of the two qubit states is individualized for each qubit in the vicinity of the magnet. This is advantageous for quantum computing. One magnet can be used for a plurality of qubit elements if a plurality of qubit elements is formed in a device.

The magnet is arranged spaced apart from the quantum well structure against the first direction. The magnet lies below the quantum well structure and also below the base layer adjacent to the quantum well structure and—if present—also below the insulation layer adjacent to the base layer, if the first direction points from bottom to top. The magnet is electrically insulated from the base layer, preferably by the insulation layer.

The magnet is provided on the side of the quantum well structure opposite the electrode array. The magnet is thus significantly closer to the quantum dot than would be the case with a magnet which would be arranged on the same side as the electrode array. This is because the influence of a magnetic field generated with a magnet on the quantum dot is greater the closer the magnet is arranged to the quantum dot. The gradient of the magnetic field is decisive for the spin-orbit coupling of the charge carriers in the quantum dot. This gradient is more pronounced the closer the magnet is situated to the quantum dot.

The arrangement of the magnet on the side of the quantum well structure opposite the electrode array is possible, in particular, on account of the base layer. A transition layer of silicon-germanium with gradually decreasing germanium proportion could basically also be provided between the quantum well structure and a silicon wafer, if the layer of the quantum well structure facing the magnet is formed from silicon-germanium, for example. The transition layer would have to have a considerable thickness, for example of 1 μm [micrometer], in order that not too many lattice defects arise as a result, however. A magnet on the underside of the transition layer would, however, be too far away from the quantum dot as a result. A substantially smaller distance between the magnet and the quantum dot can be implemented by the base layer and the preferably provided insulation layer of silicon dioxide in the case of the described qubit element, on the other hand.

In a further preferred embodiment, the qubit element further comprises a backgate arranged spaced apart against the first direction from the quantum well structure.

The backgate can be formed as a global backgate for a plurality of qubit elements. The charge carriers in the quantum dot can be influenced via the backgate. In particular, the quantum energy can be shifted by the backgate, whereby the occupation of the quantum dot can be influenced. The occupation number of the quantum dot can be set independently of an electrical field between the backgate and the electrode array with the backgate and the electrode array. The combination of backgate and electrode array results in a particularly high flexibility in the design of the qubit element, in particular with respect to electrical field gradients in the section of the quantum dot. The backgate can be formed in one piece or composed of a plurality of parts. The parts of the backgate can be arranged adjacent to one another or spaced apart from one another. Reference can also be made to a structured backgate in the latter case.

What has been said for the magnet applies correspondingly to the arrangement of the backgate. A charge carrier in the quantum dot can be influenced in a particularly targeted and rapid manner by the comparatively small distance between the backgate and the quantum dot. The valley splitting in the quantum dot is particularly large and homogeneous, so that the operating temperature of the qubit element can be selected to be particularly high. The backgate is preferably spaced apart from the edge of the quantum well structure at a distance of 30 to 200 nm [nanometers]. This relates to the edge of the quantum well structure which lies closest to the backgate.

It is possible to provide the magnet without a backgate or the backgate without a magnet. It is also possible to provide the backgate in addition to the magnet. It is preferred in this case that the backgate is electrically insulated from the magnet. It is alternatively preferred that the magnet is connected electrically conductively to the backgate. The magnet can in this respect be regarded as part of the backgate. The embodiment of the qubit element in which the backgate is at least partially magnetized is therefore preferred.

The magnet can be arranged, in particular, between the insulation layer and the remaining part of the backgate. The magnet is directly adjacent to the remaining part of the backgate and in this respect is connected electrically conductively to the remaining part of the backgate in the present embodiment. The magnet can therefore on the one hand be used to generate the magnetic field gradient for the spin-orbit coupling. The magnet is on the other hand part of the backgate and in this respect can contribute to the generation of an electrical field.

In a further preferred embodiment, the qubit element further comprises a wafer with a recess, wherein the backgate and/or the magnet are arranged within the recess. If a backgate but no magnet is provided, the backgate is arranged in the recess. If a magnet but no backgate is provided, the magnet is arranged in the recess. If a backgate and a magnet are provided, both the backgate and the magnet are preferably arranged in the recess.

The wafer is preferably a silicon wafer. The silicon wafer can be locally etched such that the backgate and/or the magnet can be inserted into a recess in the wafer. The backgate and/or the magnet can thus be brought particularly close to the quantum dot.

It is preferred, in particular, in this embodiment that the qubit element has an insulation layer of silicon dioxide abutting the base layer on a side of the base layer opposite the quantum well structure. The silicon dioxide additionally serves in this case as an etch stop for the etching of the wafer. The material of the wafer can thus be completely removed in the recess. The recess thus extends along the first direction over the entire extent of the wafer. The backgate and/or the magnet can therefore be arranged directly adjacent to the insulation layer.

A use of a qubit element formed as described is presented as a further aspect of the invention, wherein electrical voltages are applied to the electrode arrangement such that a quantum dot is formed in the quantum well of the quantum well structure.

The described advantages and features of the qubit element can be applied and transferred to the use, and vice versa.

The qubit element is preferably used at a temperature in the range of 0.01 to 4 K. This is possible, in particular, in a cryostat.

A spin of a charge carrier in the quantum dot is used for implementing a qubit in a preferred embodiment of the use.

A method for manufacturing a qubit element is presented as a further aspect of the invention. The method comprises:
a) providing a wafer, an insulation layer of silicon dioxide on a surface of the wafer, and a base layer of strained silicon adjacent to the insulation layer,
b1) providing a quantum well structure adjacent to the base layer, wherein a quantum well is formed within the quantum well structure along a first direction,
b2) locally etching the wafer on a side of the wafer opposite the insulation layer such that a recess is formed in the wafer,
c) disposing a backgate and/or a magnet within the recess etched according to step b).

The described advantages and features of the qubit element and the use can be applied and transferred to the method, and vice versa. The described qubit element can preferably be produced with the described method. The described method is preferably configured for manufacturing the described qubit element.

Steps b1) and b2) can be carried out in any desired sequence. Step b1) is preferably carried out before step b2).

In step a), a wafer, an insulation layer of silicon dioxide on a surface of the wafer, and a base layer of strained silicon adjacent to the insulation layer are provided. Providing in this case means that a wafer provided in any case with the insulation layer and the base layer of strained silicon is obtained from a supplier or that such a wafer is produced as part of the method.

A wafer with insulation layer and base layer of strained silicon can be obtained with the method also referred to as “Jülich process”, which is described in U.S. Pat. No. 6,464,780. The content of this document is incorporated by reference in its entirety as belonging to the invention. A layer structure used as an auxiliary is first grown from an Si substrate, an abutting SiGe layer, and an Si cover layer abutting the SiGe layer. The Si top layer becomes the base layer in the course of the process, i.e., has the thickness of the base layer. This is preferably at most 20 nm [nanometers], in particular between 1 and 10 nm. The SiGe is strained in this arrangement. Helium is then introduced into the layer structure and the layer structure is heated for annealing. The SiGe relaxes as a result and obtains its natural lattice constant. This continues on the comparatively thin Si top layer, such that the silicon in the Si top layer becomes strained silicon. This is the base layer. The described layer structure used as an auxiliary is placed “on the head” onto the insulation layer by wafer bonding in order to provide the base layer on the insulation layer. The SiGe layer and the Si substrate of the layer structure can be removed by selective etching. Only the base layer thus remains on the insulation layer. The quantum well structure can then be grown onto the base layer by means of molecular beam epitaxy (MBE), for example. This is carried out in step b1), in which the quantum well structure is provided on the insulation layer.

The wafer is locally etched in step b2). This is carried out from the rear side of the wafer to the extent that the etching begins on the side of the wafer opposite the insulation layer. The material of the wafer is preferably removed in the section of the recess to such an extent that the recess reaches as far as the insulation layer. This is easily possible because the silicon dioxide serves as an etch stop. The recess etched in this way can be used for a plurality of qubit elements in a device having a plurality of qubit elements.

The magnet and/or the backgate are inserted into the recess in step c). This is preferably carried out in such a way that the magnet and/or the backgate are adjacent to the insulation layer. A backgate and/or a magnet can be used globally for a plurality of qubit elements in a device having a plurality of qubit elements.

### DESCRIPTION OF THE FIGURES

The invention is explained in more detail below with reference to the figures. The figures show a particularly preferred exemplary embodiment, to which the invention is not limited, however. The figures and the size ratios presented therein are only schematic. In the figures:

FIG. 1: qubit element according to the invention,

FIG. 2: the band structure of a part of the qubit element from FIG. 1.

### DETAILED DESCRIPTION OF THE INVENTION

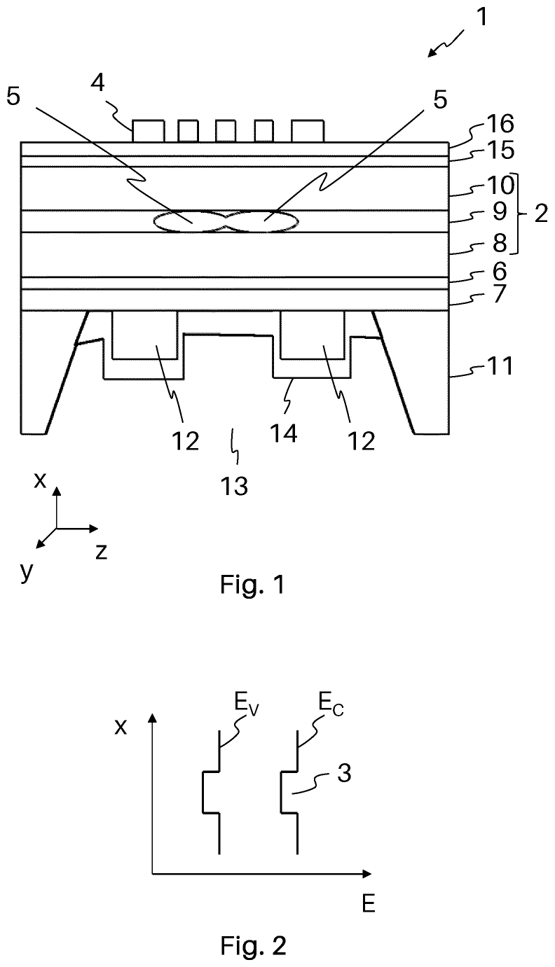

FIG. 1 shows a qubit element 1. The qubit element is described with reference to a coordinate system of a first direction x, a second direction y, and a third direction z, which are perpendicular to one another in pairs. The qubit element 1 comprises a quantum well structure 2, within which a quantum well 3 is formed along the first direction x. This can be seen in FIG. 2. The qubit element 1 further comprises an electrode array 4. The electrode array 4 is spaced apart from the quantum well structure 2 by a top layer 15 and an oxide layer 16. The electrode arrangement 4 is adapted to restrict the movement of charge carriers in the quantum well 3 in and against the second direction y and in and against the third direction z, in order to form a quantum dot 5. Two such quantum dots 5 are shown. The quantum dots 5 can be formed by applying electrical voltages to the electrode arrangement 4. The spins of charge carriers in the quantum dots 5 can respectively be used as a qubit. The spins of charge carriers in the two quantum dots 5 shown can, in particular, be used as qubits coupled to one another.

The qubit element 1 further comprises a base layer 6 formed from strained silicon adjacent to the quantum well structure 2 against the first direction x. The qubit element 1 further comprises an insulation layer 7 of silicon dioxide abutting the base layer 6 on a side of the base layer 6 opposite the quantum well structure 2. The quantum well structure 2 has three layers 8, 9, 10 following one another in the first direction x, of which a second layer 9 is formed from strained silicon, and of which a first layer 8 and a third layer 10 are respectively formed from silicon-germanium or germanium-silicon. The qubit element 1 further comprises a magnet 12 and a backgate 14 arranged spaced apart from the quantum well structure 2 against the first direction x. In the embodiment shown, the magnet 12 and—if not covered by the magnet 12—also the backgate 14 abut the insulation layer 7. The backgate 14 can be electrically insulated from the magnet 12 (by an insulation (not shown) between the magnet 12 and the backgate 14) or electrically connected to the magnet 12. The backgate 14 can be regarded as partially magnetized in the latter case. The magnet 12 forms the magnetized part of the backgate 14. The qubit element 1 further comprises a wafer 11 with a recess 13. The magnet 12 and the backgate 14 are arranged within the recess 13.

The qubit element 1 can be manufactured by first providing the wafer 11 which has the insulation layer 7 and a base layer 6 of strained silicon adjacent to the insulation layer 7 on a surface. The quantum well structure 2 adjacent to the base layer 6 can then be produced. The wafer 11 can be locally etched on a side of the wafer 11 opposite the insulation layer 7 (i.e., at the bottom in FIG. 1) such that the recess 13 is formed in the wafer 11. The insulation layer 7 serves here as an etch stop. The magnet 12 and the backgate 14 can then be arranged within the recess 13.

FIG. 2 shows the band structure of a part of the qubit element 1 from FIG. 1. The quantum well 3 can be seen at the shown conduction band EC and valence band Ev.

### REFERENCE SIGNS

1 qubit element
2 quantum well structure
3 quantum well
4 electrode array
5 quantum dot
6 base layer
7 insulation layer
8 quantum well structure first layer
9 quantum well structure second layer
10 quantum well structure third layer
11 wafer
12 magnet
13 recess
14 backgate
15 top layer
16 oxide layer
x first direction
y second direction
z third direction

1. A qubit element, comprising:
a quantum well structure, within which a quantum well is formed along a first direction(x),
an electrode arrangement adapted to restrict a movement of a charge carrier in the quantum well in and against a second direction and in and against a third direction, in order to form a quantum dot, wherein the first direction (x), the second direction, and the third direction (z) are respectively perpendicular to one another in pairs,
a base layer formed from strained silicon adjacent to the quantum well structure against the first direction.

2. The qubit element according to claim 1, further comprising an insulation layer of silicon dioxide abutting the base layer on a side of the base layer opposite the quantum well structure.

3. The qubit element according to claim 1, wherein the quantum well structure has three layers following one another in the first direction, of which the middle layer is formed from strained silicon, and of which the two remaining layers are respectively formed from silicon and germanium.

4. The qubit element according to claim 1, further comprising a magnet arranged spaced apart from the quantum well structure against the first direction.

5. The qubit element according to claim 1, further comprising a backgate arranged spaced apart from the quantum well structure against the first direction.

6. The qubit element according to claim 5, wherein the backgate is at least partially magnetized.

7. The qubit element according to claim 4, further comprising a wafer with a recess, wherein the backgate and/or the magnet are arranged within the recess.

8. (canceled)

9. (canceled)

10. A method for manufacturing a qubit element, comprising:
a) providing a wafer, an insulation layer of silicon dioxide on a surface of the wafer and a base layer of strained silicon adjacent to the insulation layer,
b1) providing a quantum well structure adjacent to the base layer, wherein a quantum well is formed within the quantum well structure along a first direction,
b2) locally etching the wafer on a side of the wafer opposite the insulation layer such that a recess is formed in the wafer,
c) disposing a backgate and/or a magnet within the recess (13) etched according to step b).

11. A method for operating a qubit element, the qubit element comprising a quantum well structure, within which a quantum well is formed along a first direction, an electrode arrangement adapted to restrict a movement of a charge carrier in the quantum well in and against a second direction and in and against a third direction, in order to form a quantum dot, wherein the first direction, the second direction, and the third direction are respectively perpendicular to one another in pairs, and a base layer formed from strained silicon adjacent to the quantum well structure against the first direction, the method comprising applying electrical voltages to the electrode arrangement such that a quantum dot is formed in the quantum well of the quantum well structure.

12. The method according to claim 11, further comprising implementing a qubit using a spin of a charge carrier in the quantum dot.
